(19) United States
(12) Patent Application Publication
(10) Pub. No.: US 2025/0329600 A1
(43) Pub. Date: Oct. 23, 2025

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: KOJI URAMOTO, Nisshin-shi (JP); MASAKI AOSHIMA, Nisshin-shi (JP)

(21) Appl. No.: 19/097,949

(22) Filed: Apr. 2, 2025

(30) Foreign Application Priority Data
Apr. 23, 2024 (JP) 2024-069807

(51) Int. Cl. H01L 23/367

(52) U.S. Cl. CPC H01L 23/367

(57) ABSTRACT

A semiconductor device includes a component-embedded substrate that includes a board, first and second semiconductor elements, first and second heat dissipation members, and a thermal interference suppression member. The first and second semiconductor elements are embedded in the board and arranged with a gap therebetween in a direction perpendicular to a thickness direction of the board. The first heat dissipation member is embedded in the board and connected to the first semiconductor element in the thickness direction. The second heat dissipation member is embedded in the board and connected to the second semiconductor element in the thickness direction. The thermal interference suppression member is embedded in the board and disposed between the first heat dissipation member and the second heat dissipation member to dissipate heat.

### CROSS REFERENCE TO RELATED APPLICATION

The present application claims the benefit of priority from Japanese Patent Application No. 2024-69807 filed on Apr. 23, 2024. The entire disclosures of the above application are incorporated herein by reference.

### TECHNICAL FIELD

The present disclosure relates to a semiconductor device.

### BACKGROUND

For example, it has been known an electronic device that includes a component-embedded substrate, a capacitor, and a first heat dissipation member. The component-embedded substrate has a first surface and a second surface opposite to the first surface in a thickness direction of the substrate. The capacitor is disposed on the first surface of the component-embedded substrate. The first heat dissipation member is disposed on the second surface of the component-embedded substrate. The component-embedded substrate includes semiconductor elements and second heat dissipation members. The semiconductor elements are embedded in the component-embedded substrate and arranged with a gap therebetween in a direction perpendicular to the thickness direction. The second heat dissipation members are embedded in the component-embedded substrate and arranged with a gap therebetween in the direction perpendicular to the thickness direction between the capacitor and the first heat dissipation member.

### SUMMARY

The present disclosure describes a semiconductor device. According to an aspect of the present disclosure, a semiconductor device includes a component-embedded substrate. The component-embedded substrate includes a board, first and second semiconductor elements embedded in the board and arranged with a gap therebetween in a direction perpendicular to a thickness direction of the board, first and second heat dissipation members embedded in the board and connected, respectively, to the first and second semiconductor elements in the thickness direction, and a thermal interference suppression member embedded in the board and disposed between the first heat dissipation member and the second heat dissipation member to dissipate heat.

### BRIEF DESCRIPTION OF DRAWINGS

Objects, features and advantages of the present disclosure will become more apparent from the following detailed description made with reference to the accompanying drawings, in which:

FIG. 1 is a cross-sectional view of a semiconductor device according to a first embodiment;

FIG. 2 is a cross-sectional view of a semiconductor device according to a comparative example;

FIG. 3 is a cross-sectional view of a semiconductor device according to a second embodiment;

FIG. 4 is a cross-sectional view of a semiconductor device according to a third embodiment;

FIG. 5 is a cross-sectional view of a semiconductor device according to a fourth embodiment;

FIG. 6 is a cross-sectional view of a semiconductor device according to a fifth embodiment;

FIG. 7 is a cross-sectional view of a semiconductor device according to a sixth embodiment;

FIG. 8 is a cross-sectional view of a semiconductor device according to a seventh embodiment;

FIG. 9 is a cross-sectional view of a semiconductor device according to an eighth embodiment; and

FIG. 10 is a cross-sectional view of a semiconductor device according to a ninth embodiment.

### DETAILED DESCRIPTION

As a related art, there is an electronic device that includes a component-embedded substrate, a capacitor on a first surface of the component-embedded substrate, and a first heat dissipation member on a second surface of the component-embedded substrate. Inside the component-embedded substrate, semiconductor elements may be arranged with a gap therebetween in a direction perpendicular to a thickness direction of the substrate, and second heat dissipation members may be arranged with a gap therebetween in the direction perpendicular to the thickness direction. In such an electronic device, when the capacitor generates heat, the heat is conducted to the first heat dissipation member via the second heat dissipation members. Thus, the second heat dissipation member facilitates the conduction of heat to the first heat dissipation member, promoting the heat dissipation of the capacitor. However, not only the capacitor but also the semiconductor elements generate heat. Since the second heat dissipation members that are connected to the semiconductor elements are arranged with the gap therebetween in the direction perpendicular to the thickness direction, the heat from the semiconductor element is easily conducted to adjacent semiconductor elements. As a result, thermal interference is likely to occur between the adjacent semiconductor elements, causing damage to the semiconductor elements.

The present disclosure provides a semiconductor device capable of suppressing mutual thermal interference between adjacent semiconductor elements.

According to an aspect of the present disclosure, a semiconductor device includes a component-embedded substrate that includes a board, a first semiconductor element, a second semiconductor element, a first heat dissipation member, a second heat dissipation member, and a thermal interference restriction member. The first semiconductor element is embedded in the board. The second semiconductor element is embedded in the board and arranged with a gap from the first semiconductor element in a direction perpendicular to a thickness direction of the board. The first heat dissipation member is embedded in the board and connected to the first semiconductor element in the thickness direction so that heat from the first semiconductor element is conducted to the first heat dissipation member. The second heat dissipation member is embedded in the board and connected to the second semiconductor element in the thickness direction so that heat from the second semiconductor element is conducted to the second heat dissipation member. The thermal interference suppression member is embedded in the board and disposed between the first heat dissipation member and the second heat dissipation member to dissipate heat to an outside of the component-embedded substrate.

As a result, the heat conducted from the first semiconductor element to the first heat dissipation member is conducted to the thermal interference suppression member. The heat conducted to the thermal interference suppression member is dissipated to the outside of the component-embedded substrate. Therefore, the heat conducted from the first semiconductor element to the first heat dissipation member is less likely to be conducted to the second heat dissipation member and the second semiconductor element. Furthermore, the heat conducted from the second semiconductor element to the second heat dissipation member is conducted to the thermal interference suppression member. The heat conducted to the thermal interference suppression member is dissipated to the outside of the component-embedded substrate. Therefore, the heat conducted from the second semiconductor element to the second heat dissipation member is less likely to be conducted to the first heat dissipation member and the first semiconductor element. Accordingly, mutual thermal interference between the first semiconductor element and the second semiconductor element is suppressed.

Hereinafter, embodiments will be described with reference to the drawings. In the following descriptions, the same or equivalent parts are denoted by the same reference numerals, and the description thereof will not be repeated.

### First Embodiment

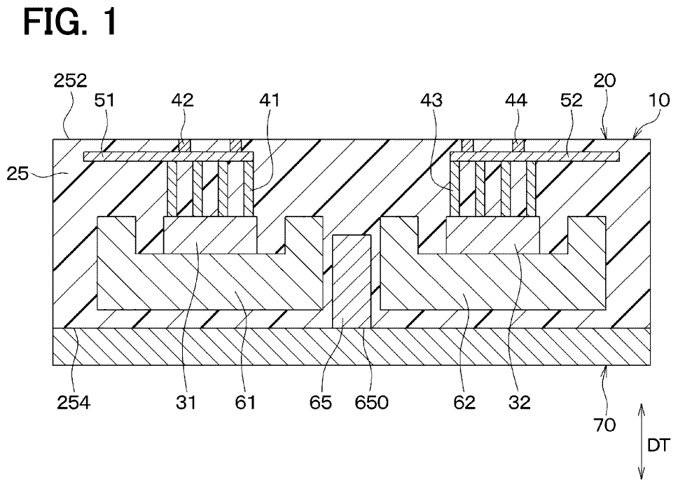

A semiconductor device according to the present embodiment suppresses mutual thermal interference between semiconductor elements arranged adjacent to each other. Specifically, as shown in FIG. 1, the semiconductor device 10 has a component-embedded substrate 20 and a cooling member 70.

The component-embedded substrate 20 has a board 25, a first semiconductor element 31, a second semiconductor element 32, a first via 41, a first wiring layer 51, a second via 42, a third via 43, a second wiring layer 52, a fourth via 44, a first heat dissipation member 61, a second heat dissipation member 62, and a thermal interference suppression member 65.

The board 25 is a printed circuit board and is made of glass epoxy resin of such as flame retardant type 4 (FR4). In the following description, the thickness direction of the board 25 will be simply referred to as the thickness direction DT.

The board 25 has a board front surface 252 and a board back surface 254. The board front surface 252 is a surface that intersects with the thickness direction DT. The board back surface 254 is a surface that intersects with the thickness direction DT and is opposite to the board front surface 252. For example, the board front surface 252 and the board back surface 254 are perpendicular to the thickness direction DT.

The first semiconductor element 31 is a metal-oxide-semiconductor field-effect transistor (MOSFET) or an insulated gate bipolar transistor (IGBT). The first semiconductor element 31 is embedded in the board 25. The first semiconductor element 31 is disposed inside the board 25 on the board front surface 252 side.

The second semiconductor element 32 is a MOSFET or an IGBT. The second semiconductor element 32 is embedded in the board 25. The second semiconductor element 32 is disposed inside the board 25 on the board front surface 252 side. The second semiconductor element 32 is arranged with a gap from the first semiconductor element 31 in a direction perpendicular to the thickness direction DT. In other words, the first semiconductor element 31 and the second semiconductor element 32 are arranged adjacent to each other in a direction perpendicular to the thickness direction DT.

The first via 41 is made of copper or the like and is therefore conductive. The first via 41 is embedded in the board 25. The first via 41 is connected to the first semiconductor element 31 on a side adjacent to the board front surface 252 in the thickness direction DT. Multiple first vias 41 are arranged with gaps therebetween in a direction perpendicular to the thickness direction DT.

The first wiring layer 51 is made of copper or the like and is therefore conductive. The first wiring layer 51 is embedded in the board 25. The first wiring layer 51 is connected to the first vias 41 on a side opposite to the first semiconductor element 31 in the thickness direction DT. The first wiring layer 51 extends in a direction perpendicular to the thickness direction DT.

The second via 42 is made of copper or the like and is therefore conductive. The second via 42 is embedded in the board 25. The second via 42 is connected to the first wiring layer 51 on a side opposite to the first via 41 in the thickness direction DT. Multiple second vias 42 are arranged with a gap therebetween in a direction perpendicular to the thickness direction DT. A portion of the second via 42, which is opposite to the first wiring layer 51, is exposed from the board front surface 252 and is connected to an electronic component such as a capacitor or a chip resistor (not shown).

The third via 43 is made of copper or the like and is therefore conductive. The third via 43 is embedded in the board 25. The third via 43 is connected to the second semiconductor element 32 on a side adjacent to the board front surface 252 in the thickness direction DT. Multiple third vias 43 are arranged with gaps therebetween in a direction perpendicular to the thickness direction DT.

The second wiring layer 52 is made of copper or the like and is therefore conductive. The second wiring layer 52 is embedded in the board 25. The second wiring layer 52 is connected to the third vias 43 on a side opposite to the second semiconductor element 32 in the thickness direction DT. The second wiring layer 52 extends in a direction perpendicular to the thickness direction DT.

The fourth via 44 is made of copper or the like and is therefore conductive. The fourth via 44 is embedded in the board 25. The fourth via 44 is connected to the second wiring layer 52 on a side opposite to the third vias 43. Multiple fourth vias 44 are arranged with a gap therebetween in a direction perpendicular to the thickness direction DT. A portion of the fourth via 44, which is opposite the second wiring layer 52, is exposed from the board front surface 252 and is connected to an electronic component such as a capacitor or chip resistor (not shown).

The first heat dissipation member 61 is made of a metal such as copper or aluminum, or graphite. Therefore, the thermal conductivity of the first heat dissipation member 61 is relatively high. The first heat dissipation member 61 is embedded in the board 25. The first heat dissipation member 61 is disposed in the board 25 on the board back surface 254 side. The first heat dissipation member 61 is connected to the first semiconductor element 31 on a side opposite to the first vias 41 in the thickness direction DT. As a result, when the first semiconductor element 31 generates heat, the heat from the first semiconductor element 31 is conducted to the first heat dissipation member 61 and dissipated.

The second heat dissipation member 62 is made of a metal such as copper or aluminum, or graphite. Therefore, the thermal conductivity of the second heat dissipation member 62 is relatively high. The second heat dissipation member 62 is embedded in the board 25. The second heat dissipation member 62 is disposed in the board 25 on the board back surface 254 side. The second heat dissipation member 62 is arranged next to the first heat dissipation member 61 with a gap therebetween in a direction perpendicular to the thickness direction DT. The second heat dissipation member 62 is connected to the second semiconductor element 32 on a side opposite to the third vias 43 in the thickness direction DT. As a result, when the second semiconductor element 32 generates heat, the heat from the second semiconductor element 32 is conducted to the second heat dissipation member 62 and dissipated.

The thermal interference suppression member 65 is made of a metal such as copper or aluminum, or graphite. Therefore, the thermal conductivity of the thermal interference suppression member 65 is relatively high. The thermal conductivity of the thermal interference suppression member 65 is higher than the thermal conductivity of the board 25. The thermal interference suppression member 65 has, for example, a cylindrical column shape having a height in the thickness direction DT. That is, the length of the thermal interference suppression member 65 in the thickness direction DT corresponds to the height of the thermal interference suppression member 65. The thermal interference suppression member 65 is embedded in the board 25. The thermal interference suppression member 65 is arranged between the first heat dissipation member 61 and the second heat dissipation member 62. With this arrangement, the heat conducted from the first semiconductor element 31 to the first heat dissipation member 61 and the heat conducted from the second semiconductor element 32 to the second heat dissipation member 62 are conducted to the thermal interference suppression member 65. The heats conducted from the first heat dissipation member 61 and the second heat dissipation member 62 to the thermal interference suppression member 65 are dissipated to the outside of the component-embedded substrate 20.

The thermal interference suppression member 65 has an exposed surface 650. The exposed surface 650 is a surface that intersects with the thickness direction DT and is exposed from the board 25. For example, the exposed surface 650 is perpendicular to the thickness direction DT and is exposed from the board back surface 254.

The thermal interference suppression member 65 is formed by via fill plating, stacked via, copper inlay, crimping, and the like. The via-fill plating is a technique of plating a hole formed in the board 25 by drilling or the like. The stacked via is forming by plating on each layer of the board 25. The copper inlay is a technique of press-fitting a copper pin or the like into a hole formed in the board 25 by drilling or the like. The crimping is a technique in which a member is inserted into a hole in the board 25 formed by drilling or the like, and the inserted member is deformed to be fixed to the board 25.

The cooling member 70 is connected to the board back surface 254 and the exposed surface 650 of the thermal interference suppression member 65 and cools the thermal interference suppression member 65. For this reason, the heat conducted to the thermal interference suppression member 65 is conducted to the cooling member 70 and is thus dissipated. As a result, the heat from the first heat dissipation member 61 and the heat from the second heat dissipation member 62 are easily conducted to the thermal interference suppression member 65. For example, the cooling member 70 is a pipe or the like, and the thermal interference suppression member 65 is cooled by a cooling water flowing through the cooling member 70. Alternatively, the cooling member 70 may be a fin which is made of a material having a relatively high thermal conductivity, such as a metal. Examples of the metal include copper, aluminum, and graphite. Examples of the fin include a fin composed of multiple flat plates arranged side by side, a corrugated fin, and a pin fin.

The semiconductor device 10 of the first embodiment has the configurations as described above. Next, the suppression of mutual thermal interference between the first semiconductor element 31 and the second semiconductor element 32 in the semiconductor device 10 will be described.

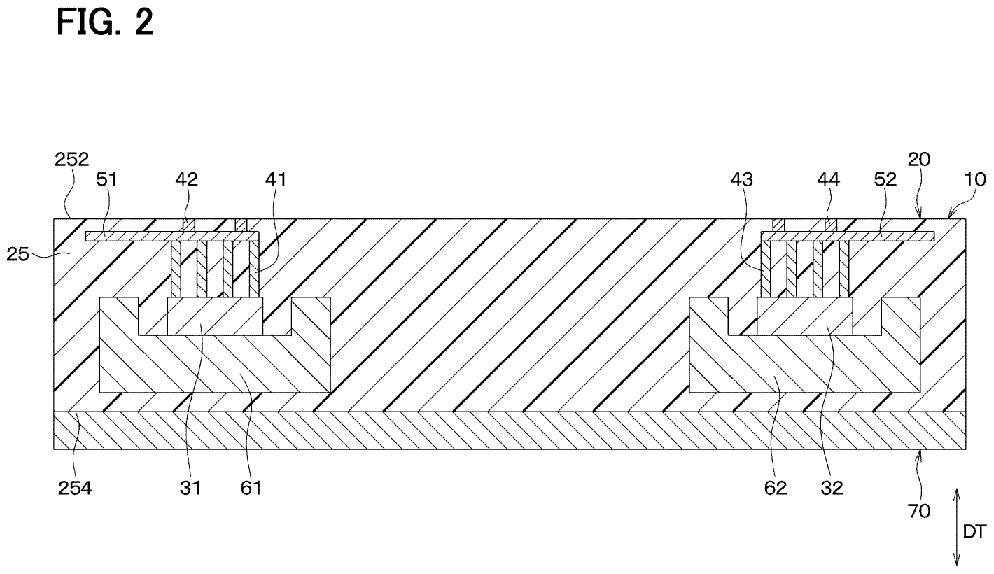

In a semiconductor device 10 of a comparative example shown in FIG. 2, a first semiconductor element 31 and a second semiconductor element 32 generate heat. In this configuration, due to a first heat dissipation member 61 and a second heat dissipation member 62, the heat of the first semiconductor element 31 is easily conducted to the second semiconductor element 32 and the heat of the second semiconductor element 32 is easily conducted to the first semiconductor element 31. Therefore, thermal interference is likely to occur between the first semiconductor element 31 and the second semiconductor element 32, which are adjacent to each other. As a result, the first semiconductor element 31 and the second semiconductor element 32 are likely to be damaged. Furthermore, the bonding between the first semiconductor element 31 and the first heat dissipation member 61 is likely to be deteriorated. Likewise, the bonding between the second semiconductor element 32 and the second heat dissipation member 62 is likely to be deteriorated. In order to suppress the mutual thermal interference between the first semiconductor element 31 and the second semiconductor element 32 adjacent to each other, it may be conceivable to increase a distance between the first semiconductor element 31 and the second semiconductor element 32 adjacent to each other. If the distance between the first semiconductor element 31 and the second semiconductor element 32 adjacent to each other is increased, the component-embedded substrate 20 is increased in size.

In contrast, in the semiconductor device 10 of the present embodiment, the component-embedded substrate 20 is provided with the thermal interference suppression member 65. The thermal interference suppression member 65 is embedded in the board 25 and is disposed between the first heat dissipation member 61 and the second heat dissipation member 62. Therefore, the heat of the first heat dissipation member 61 and the heat of the second heat dissipation member 62 are conducted to the thermal interference suppression member 65, and the thermal interference suppression member 65 dissipates the heat from the first heat dissipation member 61 and the heat from the second heat dissipation member 62 to the outside of the component-embedded substrate 20.

In this way, the heat conducted from the first semiconductor element 31 to the first heat dissipation member 61 is conducted to the thermal interference suppression member 65. Further, the heat conducted to the thermal interference suppression member 65 is dissipated to the outside of the component-embedded substrate 20. As a result, the heat conducted from the first semiconductor element 31 to the first heat dissipation member 61 is less likely to be conducted to the second heat dissipation member 62 and the second semiconductor element 32. Likewise, the heat conducted from the second semiconductor element 32 to the second heat dissipation member 62 is conducted to the thermal interference suppression member 65. Further, the heat conducted to the thermal interference suppression member 65 is dissipated to the outside of the component-embedded substrate 20. As a result, the heat conducted from the second semiconductor element 32 to the second heat dissipation member 62 is less likely to be conducted to the first heat dissipation member 61 and the first semiconductor element 31. Accordingly, the mutual thermal interference between the first semiconductor element 31 and the second semiconductor element 32 is suppressed.

In addition, since the mutual thermal interference between the first semiconductor element 31 and the second semiconductor element 32 is suppressed, deterioration of the bonding between the first semiconductor element 31 and the first heat dissipation member 61 and the bonding between the second semiconductor element 32 and the second heat dissipation member 62 is suppressed. Moreover, the distance between the first semiconductor element 31 and the second semiconductor element 32 in the direction perpendicular to the thickness direction DT can be reduced. As a result, it is possible to suppress the increase in size of the component-embedded substrate 20.

In addition, since the wiring inside the semiconductor device 10 can be made small, an increase in the inductance of the semiconductor device 10 is suppressed. Since the increase in the inductance of the semiconductor device 10 is suppressed, a decrease in the switching speed of the first semiconductor element 31 and the second semiconductor element 32 is suppressed. As a result, the switching loss of the first semiconductor element 31 and the second semiconductor element 32 is suppressed.

The semiconductor device 10 according to the present embodiment also achieves the following effects.

(1-1) The thermal interference suppression member 65 has the exposed surface 650. The exposed surface 650 intersects with the thickness direction DT and is exposed from the board 25. In this case, the exposed surface 650 is exposed from the board back surface 254. The semiconductor device 10 also includes the cooling member 70. The cooling member 70 is connected to the exposed surface 650 and cools the thermal interference suppression member 65.

As a result, the heat conducted to the thermal interference suppression member 65 is conducted to the cooling member 70 and dissipated. For this reason, the heat conducted from the first semiconductor element 31 to the first heat dissipation member 61 and the heat conducted from the second semiconductor element 32 to the second heat dissipation member 62 are more likely to be conducted to the thermal interference suppression member 65, and are therefore more likely to be dissipated to the outside of the component-embedded substrate 20. Accordingly, the thermal interference suppression member 65 improves the effect of suppressing the thermal interference.

(1-2) The thermal conductivity of the thermal interference suppression member 65 is higher than the thermal conductivity of the board 25.

For this reason, the heat conducted from the first semiconductor element 31 to the first heat dissipation member 61 and the heat conducted from the second semiconductor element 32 to the second heat dissipation member 62 are more likely to be conducted to the thermal interference suppression member 65 than to the board 25, and are therefore more likely to be dissipated to the outside of the component-embedded substrate 20. Accordingly, the effect of suppressing the thermal interference by the thermal interference suppression member 65 improves.

### Second Embodiment

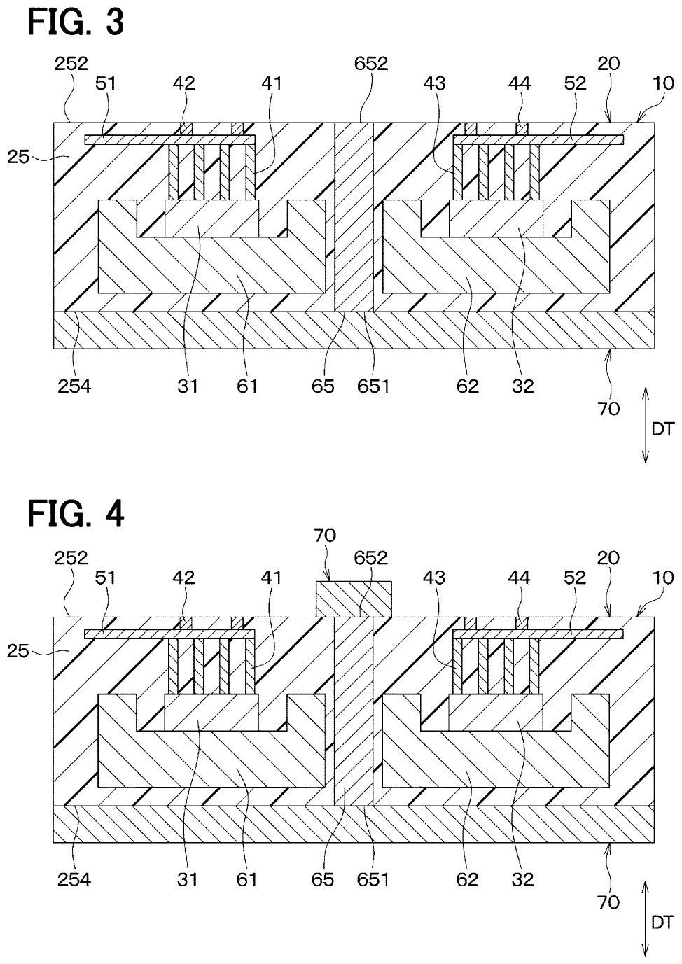

As shown in FIG. 3, a semiconductor device 10 of a second embodiment is different from the semiconductor device 10 of the first embodiment in the form of the thermal interference suppression member 65. The other configurations of the second embodiment are similar to those of the first embodiment.

Specifically, the thermal interference suppression member 65 extends in the thickness direction DT and penetrates the board 25 from the board front surface 252 to the board back surface 254. Therefore, the thermal interference suppression member 65 has a first exposed surface 651 and a second exposed surface 652, in place of the exposed surface 650 of the first embodiment.

The first exposed surface 651 corresponds to the exposed surface 650. The first exposed surface 651 intersects with the thickness direction DT and is exposed from the board back surface 254. For example, the first exposed surface 651 is perpendicular to the thickness direction DT. Furthermore, the first exposed surface 651 is connected to the cooling member 70.

The second exposed surface 652 is a surface of the thermal interference suppression member 65 opposite to the first exposed surface 651 in the thickness direction DT. The second exposed surface 652 intersects with the thickness direction DT and is exposed from the board front surface 252. For example, the second exposed surface 652 is perpendicular to the thickness direction DT.

The semiconductor device 10 of the second embodiment is configured as described above. The second embodiment achieves effects similar to the effects achieved by the first embodiment.

### Third Embodiment

As shown in FIG. 4, a semiconductor device 10 of a third embodiment is different from the semiconductor device 10 of the second embodiment in the form of the cooling member 70. The other configurations of the third embodiment are similar to those of the second embodiment.

Specifically, the semiconductor device 10 includes multiple cooling members 70. For example, the cooling members 70 are connected not only to the board back surface 254 and the first exposed surface 651, but also to the second exposed surface 652. Furthermore, the cooling members 70 are connected to a part of the board front surface 252 so as not to interfere with electronic components such as capacitors and chip resistors (not shown) connected to the second vias 42 and the fourth vias 44. For example, a part of the cooling members 70 is disposed on the board back surface 254, and another part of the cooling members 70 is disposed at a part on the board front surface 252.

The semiconductor device 10 of the third embodiment is configured as described above. The third embodiment achieves effects similar to the effects achieved by the second embodiment.

### Fourth Embodiment

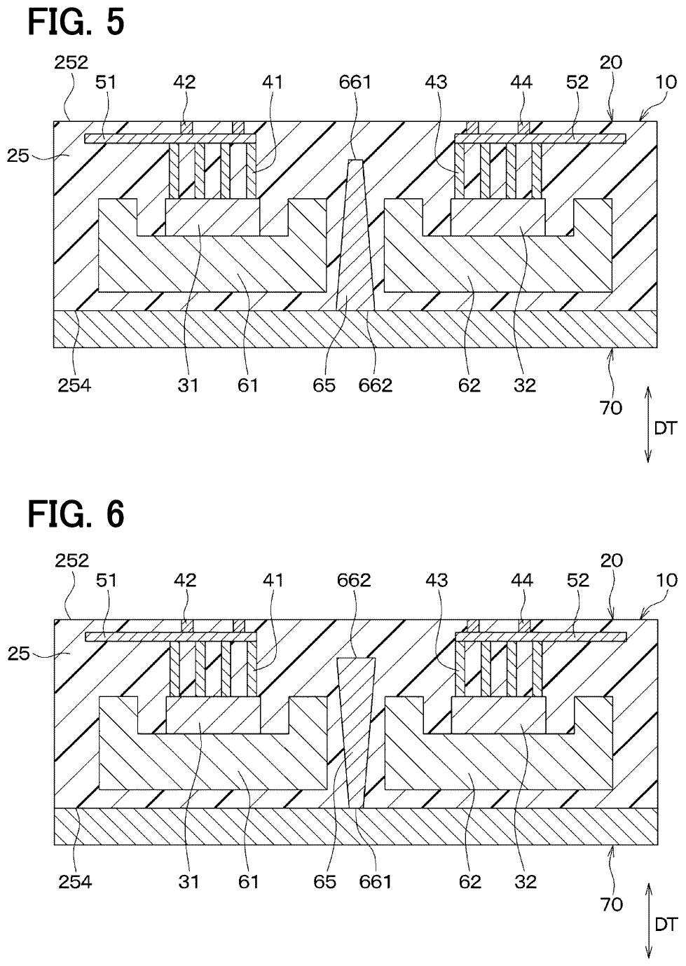

As shown in FIG. 5, a semiconductor device 10 of the fourth embodiment is different from the first embodiment in the form of the thermal interference suppression member 65. The other configurations of the fourth embodiment are similar to those of the first embodiment.

Specifically, in place of having the cylindrical column shape, the thermal interference suppression member 65 has a truncated cone shape having the height in the thickness direction DT. Moreover, the thermal interference suppression member 65 has a first surface 661 and a second surface 662, in place of the exposed surface 650.

The first surface 661 and the second surface 662 are surfaces that intersect with the thickness direction DT. For example, the first surface 661 and the second surface 662 are perpendicular to the thickness direction DT. In addition, the area of the second surface 662 is larger than the area of the first surface 661. The second surface 662 is exposed from the board back surface 254 and is connected to the cooling member 70.

The semiconductor device 10 of the fourth embodiment is configured as described above. The fourth embodiment achieves effects similar to the effects achieved by the first embodiment. The fourth embodiment also achieves the following effects.

(2) The thermal interference suppression member 65 has the truncated cone shape that has the height as the length in the thickness direction DT. Furthermore, the thermal interference suppression member 65 has the first surface 661 and the second surface 662. The area of the second surface 662 is larger than the area of the first surface 661. In addition, the second surface 662 is exposed from the board back surface 254 and is connected to the cooling member 70.

As a result, assumed that the volume of the thermal interference suppression member 65 is fixed, the size of the surface exposed from the board back surface 254 can be larger than that in a case where the thermal interference suppression member 65 has a cylindrical column shape. Therefore, the thermal interference suppression member 65 can be easily cooled by the cooling member 70. With this, the heat from the first heat dissipation member 61 and the heat from the second heat dissipation member 62 are more likely to be conducted to the thermal interference suppression member 65, and are therefore easily dissipated to the outside of the component-embedded substrate 20. Accordingly, the effect of suppressing the thermal interference by the interference suppression member 65 improves.

In addition, in a case where the radius and the height of the thermal interference suppression member 65 are fixed, the size of the thermal interference suppression member 65 having the truncated cone shape can be made smaller than the thermal interference suppression member 65 having the cylindrical column shape. Therefore, the amount of material used to form the thermal interference suppression member 65 can be reduced. The costs of the thermal interference suppression member 65 can be reduced, and therefore the costs of the semiconductor device 10 can be reduced.

### Fifth Embodiment

As shown in FIG. 6, a semiconductor device 10 of a fifth embodiment is different from the semiconductor device 10 of the first embodiment in the form of the thermal interference suppression member 65. The other configurations of the fifth embodiment are similar to those of the fourth embodiment.

Specifically, in place of the second surface 662 being exposed as in the fourth embodiment, the first surface 661 is exposed from the board back surface 254 and is connected to the cooling member 70.

The semiconductor device 10 of the fifth embodiment is configured as described above. The fifth embodiment achieves effects similar to the effects achieved by the fourth embodiment.

### Sixth Embodiment

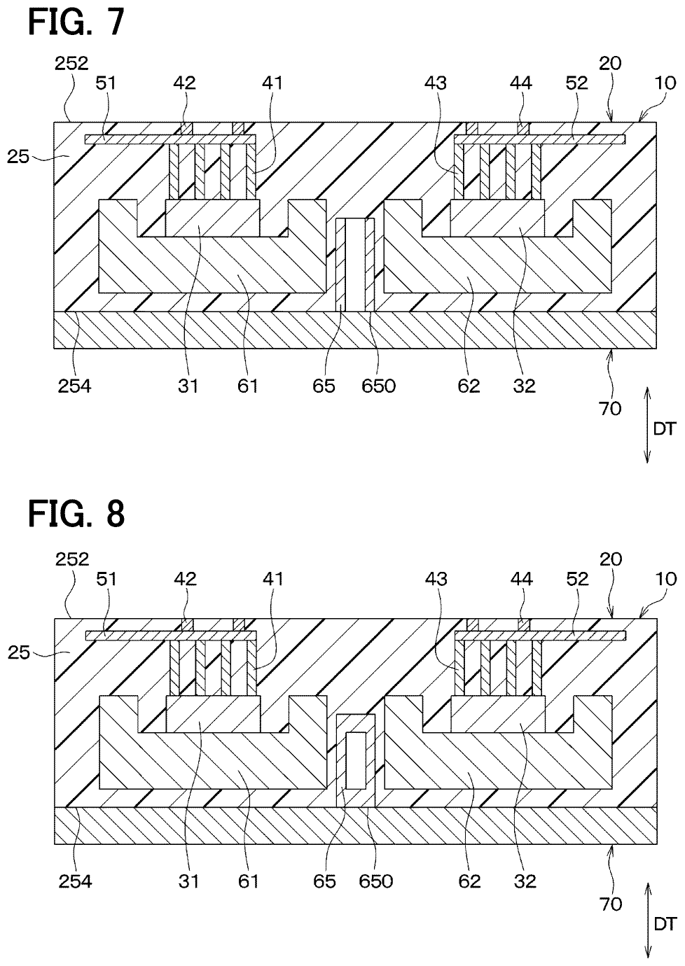

As shown in FIG. 7, a semiconductor device 10 of a sixth embodiment is different from the semiconductor device 10 of the first embodiment in the form of the thermal interference suppression member 65. The other configurations of the sixth embodiment are similar to those of the first embodiment.

Specifically, the thermal interference suppression member 65 is hollow, in place of being solid. For this reason, a space is formed inside the thermal interference suppression member 65. Furthermore, both ends of the thermal interference suppression member 65 in the thickness direction DT are open. In this case, therefore, the thermal interference suppression member 65 has a cylindrical or tubular shape.

The semiconductor device 10 of the sixth embodiment is configured as described above. The sixth embodiment achieves effects similar to the effects achieved by the first embodiment. The sixth embodiment also achieves the following effects.

(3) The space is defined inside the thermal interference suppression member 65. Because the thermal conductivity of the space is relatively small, the heat conducted from the first semiconductor element 31 to the thermal interference suppression member 65 via the first heat dissipation member 61 is less likely to be conducted to the second heat dissipation member 62 and the second semiconductor element 32. Furthermore, the heat conducted from the second semiconductor element 32 to the thermal interference suppression member 65 via the second heat dissipation member 62 is less likely to be conducted to the first heat dissipation member 61 and the first semiconductor element 31. Therefore, the effect of suppressing the thermal interference by the thermal interference suppression member 65 improves.

### Seventh Embodiment

As shown in FIG. 8, a semiconductor device 10 of a seventh embodiment is different from the semiconductor device 10 of the sixth embodiment in the form of the thermal interference suppression member 65. The other configurations of the seventh embodiment are similar to those of the sixth embodiment.

Specifically, both ends of the thermal interference suppression member 65 in the thickness direction DT are closed, in place of being open as in the sixth embodiment. Therefore, the thermal interference suppression member 65 is formed in a cylindrical shape with bottomed ends. However, the thermal interference suppression member 65 is not limited to the configuration in which both the ends in the thickness direction DT are closed. For example, one end of the thermal interference suppression member 65 in the thickness direction DT may be closed and the other end of the thermal interference suppression member 65 in the thickness direction DT may be open.

The semiconductor device 10 of the seventh embodiment is configured as described above. The seventh embodiment achieves the effects similar to the effects achieved by the sixth embodiment.

### Eighth Embodiment

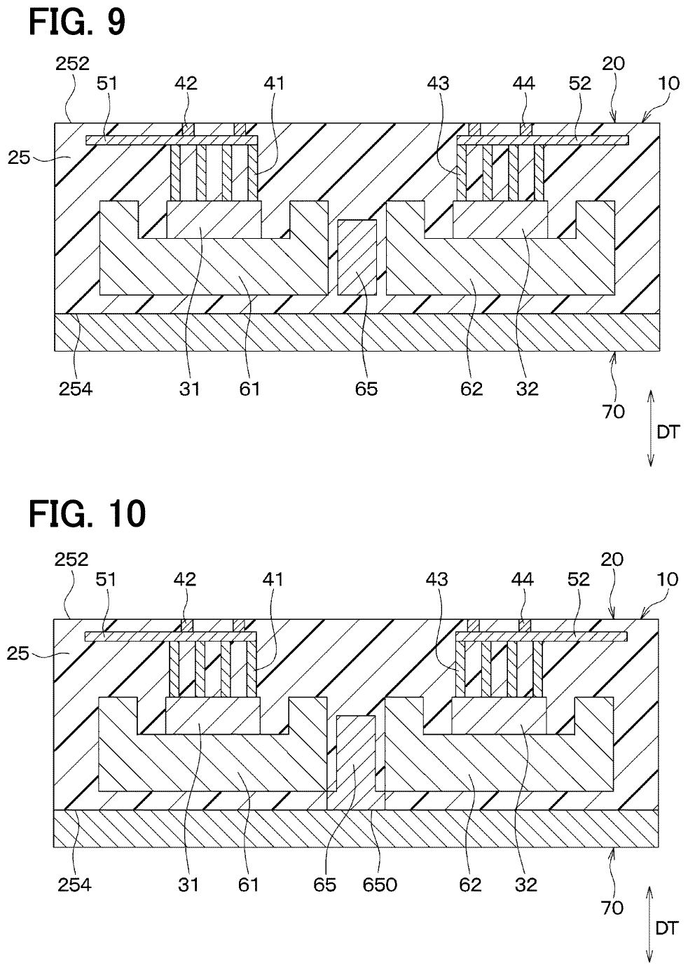

As shown in FIG. 9, a semiconductor device 10 of an eighth embodiment is different from the semiconductor device 10 of the first embodiment in the form of the thermal interference suppression member 65. The other configurations of the eighth embodiment are similar to those of the first embodiment.

Specifically, the thermal interference suppression member 65 is not exposed from the board 25. Therefore, the thermal interference suppression member 65 does not have the exposed surface 650.

The semiconductor device 10 of the eighth embodiment is configured as described above. The eighth embodiment achieves the effects similar to the effects achieved by the first embodiment.

### Ninth Embodiment

As shown in FIG. 10, a semiconductor device 10 of a ninth embodiment is different from the semiconductor device 10 of the first embodiment in the form of the thermal interference suppression member 65. The other configurations of the ninth embodiment are similar to those of the first embodiment.

Specifically, in place of being cylindrical in shape, the thermal interference suppression member 65 has a T-shape in cross section defined along the thickness direction DT.

The semiconductor device 10 of the ninth embodiment is configured as described above. The ninth embodiment achieves the effects similar to the effects achieved by the first embodiment.

### OTHER EMBODIMENTS

The present disclosure is not limited to the embodiments described above, and can be modified in various other ways. In each of the embodiments described above, individual elements or features of a particular embodiment are not necessarily essential unless it is specifically stated that the elements or the features are essential, or unless the elements or the features are obviously essential in principle.

The embodiments described above may be combined as appropriate.

What is claimed is:

1. A semiconductor device comprising a component-embedded substrate,
the component-embedded substrate including:
a board;
a first semiconductor element that is embedded in the board;
a second semiconductor element that is embedded in the board and arranged with a gap from the first semiconductor element in a direction perpendicular to a thickness direction of the board;
a first heat dissipation member that is embedded in the board and connected to the first semiconductor element in the thickness direction;
a second heat dissipation member that is embedded in the board and connected to the second semiconductor element in the thickness direction; and
a thermal interference suppression member that is embedded in the board and disposed between the first heat dissipation member and the second heat dissipation member to dissipate heat.

2. The semiconductor device according to claim 1, wherein
the thermal interference suppression member has an exposed surface that intersects with the thickness direction and is exposed from the board,
the semiconductor device further comprising
a cooling member that is connected to the exposed surface of the thermal interference suppression member.

3. The semiconductor device according to claim 2, wherein
the board has a board front surface adjacent to the first semiconductor element and the second semiconductor element and a board back surface opposite to the board front surface in the thickness direction,
the board front surface and the board back surface intersect with the thickness direction, and
the exposed surface of the thermal interference suppression member is exposed from the board back surface.

4. The semiconductor device according to claim 1, wherein
the board has a board front surface adjacent to the first semiconductor element and the second semiconductor element and a board back surface opposite to the board front surface in the thickness direction,
the board front surface and the board back surface intersect with the thickness direction, and
the thermal interference suppression member extends in the thickness direction and penetrates the board from the board front surface to the board back surface.

5. The semiconductor device according to claim 1, wherein
the thermal interference suppression member has a truncated cone shape having a height in the thickness direction.

6. The semiconductor device according to claim 5, wherein
the thermal interference suppression member has a first surface that intersects with the thickness direction and a second surface that intersects with the thickness direction and has an area larger than that of the first surface,
the board has a board front surface adjacent to the first semiconductor element and the second semiconductor element and a board back surface opposite to the board back surface in the thickness direction,
the board front surface and the board back surface intersect with the thickness direction,
the second surface of the thermal interference suppression member is exposed from the board back surface,
the semiconductor device further comprising
a cooling member that is connected to the second surface of the thermal interference suppression member.

7. The semiconductor device according to claim 1, wherein
the thermal interference suppression member has a hollow shape defining a space therein.

8. The semiconductor device according to claim 1, wherein
the thermal interference suppression member has a thermal conductivity higher than that of the board.
